(19) United States
(12) Patent Application Publication
(10) Pub. No.: US 2021/0257269 A1
(43) Pub. Date: Aug. 19, 2021

(54) SEMICONDUCTOR DEVICE

(71) Applicant: FUJI ELECTRIC CO., LTD., Kawasaki-shi (JP)

(72) Inventor: Katsumi TANIGUCHI, Matsumoto-city (JP)

(73) Assignee: FUJI ELECTRIC CO., LTD., Kawasaki-shi (JP)

(21) Appl. No.: 17/156,787

(22) Filed: Jan. 25, 2021

(30) Foreign Application Priority Data
Feb. 18, 2020 (JP) 2020-025715

(51) Int. Cl. H01L 23/053; H01L 23/14; H01L 23/498; H01L 23/31

(52) U.S. Cl. CPC H01L 23/053; H01L 23/142; H01L 23/49838; H01L 24/48; H01L 2224/48137; H01L 2224/48175; H01L 23/3121

(57) ABSTRACT

A semiconductor device having a base circuit board, a case surrounding the base circuit board to demarcate, in a plan view, an opening area in which the base circuit board is disposed, and a sealing member that seals the base circuit board disposed in the case. The base circuit board includes a metal base substrate, a resin layer formed on the metal base substrate, and a circuit pattern formed on the resin layer. The case has an inner wall surface that faces an outer peripheral side surface of the base circuit board, and that includes a first inner wall portion which is in surface contact with an outer peripheral side surface of the metal base substrate, and a second inner wall portion that is separate from the outer peripheral side surface of the base circuit board, to thereby have a first gap therebetween filled with the sealing member.

### CROSS-REFERENCE TO RELATED APPLICATION

This application is based upon and claims the benefit of priority of the prior Japanese Patent Application No. 2020-025715, filed on Feb. 18, 2020, the entire contents of which are incorporated herein by reference.

### BACKGROUND OF THE INVENTION

### 1. Field of the Invention

The embodiments discussed herein relate to a semiconductor device.

### 2. Background of the Related Art

Semiconductor devices include power devices and are used as power converters. The power devices include semiconductor chips such as an insulated gate bipolar transistor (IGBT) and a power metal oxide semiconductor field effect transistor (MOSFET). Such a semiconductor device includes at least semiconductor chips, a ceramic circuit board over which the semiconductor chips are disposed, and a radiation plate over which the ceramic circuit board is disposed. The ceramic circuit board includes an insulating plate and circuit patterns formed over the insulating plate. Furthermore, the semiconductor device includes a case for housing the ceramic circuit board over which the semiconductor chips are disposed and which is disposed over the radiation plate and a sealing member which seals an area enclosed by the case and the radiation plate.

In this case, a gap may occur between the ceramic circuit board and the sealing member according to the difference in thermal expansion coefficient between the ceramic circuit board and the sealing member or due to residual stress caused by the curing shrinkage of the sealing member. A crack or the like may appear in the ceramic circuit board with this gap as the starting point.

Accordingly, for example, the formation of a groove in a radiation plate outside a disposition area of a ceramic circuit board disposed over the radiation plate was proposed (see, for example, Japanese Laid-open Patent Publication No. 2016-195224 and Japanese Laid-open Patent Publication No. 2007-184315). Furthermore, the formation of a concavity in a lower end portion or an inner wall of a case was proposed (see, for example, International Publication Pamphlet No. WO2019/049400 and International Publication Pamphlet No. WO2019/008828). The anchor effect of a sealing member is produced or the area of adhesion between the case and a sealing member is increased by these methods. This suppresses peeling of the sealing member. On the other hand, there is a fear that working the radiation plate or the case in this way will decrease the strength. Accordingly, a method for properly selecting a sealing member which hardly peels off was also proposed (see, for example, Japanese Laid-open Patent Publication No. 2008-270469).

If sealing is performed with a sealing member without using a case, an undercut portion is formed in a side of a circuit pattern and the undercut portion is filled with a sealing member. This improves adhesion between a ceramic circuit board and the sealing member (see, for example, Japanese Laid-open Patent Publication No. 2015-70107). Furthermore, in a similar case, for example, two metal layers are laminated over an insulating plate of a ceramic circuit board and an end surface of the uppermost metal layer is made to protrude from an end surface of the undermost metal layer in the direction of a plane. As a result, a space is formed between the uppermost metal layer and the insulating plate. When the ceramic circuit board is sealed with a sealing member, the space is filled with the sealing member and adhesion between the ceramic circuit board and the sealing member is improved (see, for example, Japanese Laid-open Patent Publication No. 2015-28998).

By the way, with semiconductor devices a metal base substrate having a front surface over which an insulating resin layer is formed may be used in place of a ceramic circuit board. In this case, there is no need to use a radiation plate. As a result, a reduction in costs, miniaturization of a semiconductor device, and the like are realized.

With semiconductor devices using a metal base substrate, sealing may be performed in a case with a sealing member. In that case, the sealing member may peel off due to stress caused by the difference in thermal expansion coefficient between the metal base substrate and the sealing member, residual stress caused by the curing shrinkage of the sealing member, or the like. Accordingly, there is need to suppress peeling of the sealing member, and the like.

### SUMMARY OF THE INVENTION

According to an aspect, there is provided a semiconductor device having a base circuit board including a metal base substrate, a resin layer formed on a front surface of the metal base substrate, and a circuit pattern formed on a front surface of the resin layer; a case which surrounds the base circuit board to demarcate, in a plan view of the semiconductor device, an opening area in which the base circuit board is disposed; and a sealing member that seals the base circuit board disposed in the case, wherein the case has an inner wall surface that faces an outer peripheral side surface of the base circuit board, and that includes: a first inner wall portion which is in surface contact with an outer peripheral side surface of the metal base substrate; and a second inner wall portion that is separate from the outer peripheral side surface of the base circuit board, to thereby have a first gap therebetween that is filled with the sealing member.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF THE DRAWINGS

FIG. 1 is a longitudinal sectional view of a semiconductor device according to a first embodiment;

FIG. 2 is a transverse sectional view of the semiconductor device according to the first embodiment;

FIG. 3 is a longitudinal sectional view of a semiconductor device taken as a reference example (part 1);

FIG. 4 is a longitudinal sectional view of a semiconductor device taken as a reference example (part 2);

FIG. 5 is a longitudinal sectional view of a semiconductor device according to a second embodiment;

FIG. 6 is a longitudinal sectional view of a semiconductor device according to a third embodiment;

FIG. 7 is a longitudinal sectional view of a semiconductor device according to a fourth embodiment;

FIG. 8 is a longitudinal sectional view of a semiconductor device according to a fifth embodiment;

FIG. 9 is a longitudinal sectional view of a semiconductor device according to a sixth embodiment;

FIG. 10 is a transverse sectional view of the semiconductor device according to the sixth embodiment; and

FIG. 11 is a longitudinal sectional view of a semiconductor device according to a seventh embodiment.

### DETAILED DESCRIPTION OF THE INVENTION

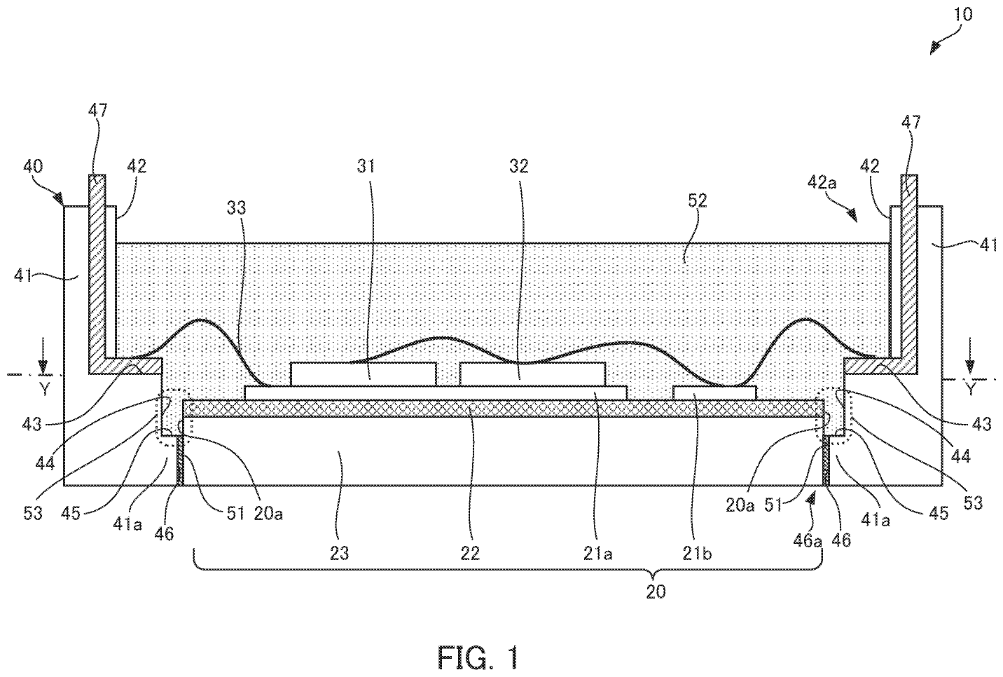

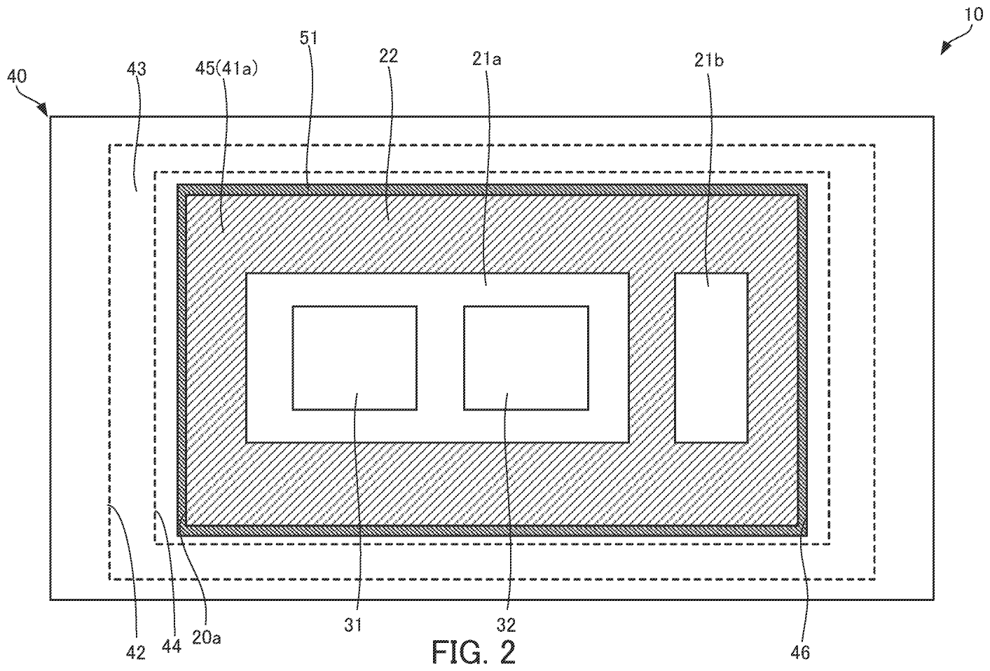

Embodiments will now be described by the use of the accompanying drawings. In the embodiments a “front surface (upper surface)” indicates a surface (direction) of a semiconductor device 10 of FIG. 1 which faces upward. For example, a surface (mounted side) of a base circuit board 20 over which semiconductor chips 31 and 32 are mounted is a “front surface (upper surface).” A “back surface (lower surface)” indicates a surface (direction) of the semiconductor device 10 of FIG. 1 which faces downward. For example, a surface (mounted side) of the base circuit board 20 to which a metal base substrate 23 is bonded is a back surface (lower surface). In FIGS. 2 through 11, a “front surface (upper surface)” and a “back surface (lower surface)” also mean the same directions.

### First Embodiment

A semiconductor device according to a first embodiment will be described by the use of FIG. 1 and FIG. 2. FIG. 1 is a longitudinal sectional view of a semiconductor device according to a first embodiment. FIG. 2 is a transverse sectional view of the semiconductor device according to the first embodiment. FIG. 2 is a transverse sectional view taken along the dot-dash line Y-Y of FIG. 1. As illustrated in FIG. 1, the semiconductor device 10 includes the semiconductor chips 31 and 32 and the base circuit board 20 having the front surface to which the semiconductor chips 31 and 32 are bonded. Furthermore, with the semiconductor device 10 these parts are housed in a case 40 and are sealed with a sealing member 52. In FIG. 2, the sealing member 52 and bonding wires 33 are not illustrated.

The base circuit board 20 includes circuit patterns 21a and 21b, an insulating resin layer 22 having a front surface over which the circuit patterns 21a and 21b are disposed, and the metal base substrate 23 having a front surface over which the insulating resin layer 22 is disposed.

The circuit patterns 21a and 21b are made of a material, such as copper, aluminum, or an alloy containing at least one of them, having good electrical conductivity. The thickness of the circuit patterns 21a and 21b is preferably greater than or equal to 0.10 mm and smaller than or equal to 2.00 mm. The thickness of the circuit patterns 21a and 21b is more preferably greater than or equal to 0.20 mm and smaller than or equal to 1.00 mm. The semiconductor chips 31 and 32 are bonded to the circuit pattern 21a with solder therebetween. Wiring members, such as a bonding wire, a lead frame, and a connection terminal, and electronic parts may be properly disposed at need over the circuit patterns 21a and 21b in addition to the semiconductor chips 31 and 32. Plating treatment may be performed on the circuit patterns 21a and 21b by the use of a material, such as aluminum, nickel, titanium, chromium, molybdenum, tantalum, niobium, tungsten, vanadium, bismuth, zirconium, hafnium, gold, silver, platinum, palladium, or an alloy containing at least one of them, having high corrosion resistance. The number, disposition positions, or shape of the circuit patterns 21a and 21b illustrated in FIG. 1 and FIG. 2 is an example. The number, disposition positions, or shape of the circuit patterns 21a and 21b may be selected properly by design.

The insulating resin layer 22 is made of resin having low thermal resistance and a high insulating property. For example, such resin is a thermosetting resin. A thermally conductive filler may be contained in a thermosetting resin. This decreases the thermal resistance of the insulating resin layer 22 further and makes the difference in thermal expansion coefficient between the insulating resin layer 22 and the metal base substrate 23 small. For example, at least one of epoxy resin, cyanate resin, polyimide resin, benzoxazine resin, unsaturated polyester resin, phenolic resin, melamine resin, silicone resin, maleimide resin, acrylic resin, and polyamide (PA) resin is used as a thermosetting resin. At least one of oxide, such as silicon oxide or aluminum oxide, and nitride, such as silicon nitride, aluminum nitride, or boron nitride, is used as a thermally conductive filler. Furthermore, hexagonal boron nitride may be used as a thermally conductive filler. The thickness of the insulating resin layer 22 depends on the rated voltage of the semiconductor device 10. That is to say, as the rated voltage of the semiconductor device 10 increases, it is desirable to increase the thickness of the insulating resin layer 22. On the other hand, it is desirable to decrease the thermal resistance of the insulating resin layer 22. For this reason, the insulating resin layer 22 is made as thin as possible. For example, the thickness of the insulating resin layer 22 is greater than or equal to 0.05 mm and smaller than or equal to 0.50 mm.

The metal base substrate 23 is made of metal, such as aluminum, iron, silver, copper, or an alloy containing at least one of them, having high thermal conductivity. For example, a composite metal material, such as aluminum-silicon carbide (Al-SiC) or magnesium-silicon carbide (Mg-SiC), may be used as such an alloy. Furthermore, in order to improve corrosion resistance, a material, such as nickel, may be formed on the surface of the metal base substrate 23 by plating treatment or the like. To be concrete, a nickel-phosphorus alloy, a nickel-boron alloy, or the like may be used in place of nickel. The thickness of a plating film is preferably greater than or equal to 1 μm. The thickness of a plating film is more preferably greater than or equal to 5 μm. In addition, as described later, a cooling unit (not illustrated) may be fixed to the back surface of the case 40 including the metal base substrate 23 with solder, silver solder, or the like therebetween. This improves the heat dissipation property of the semiconductor device 10. For example, this cooling unit is made of metal, such as aluminum, iron, silver, copper, or an alloy containing at least one of them, having high thermal conductivity. Moreover, a heat sink made up of one or more fins, a water-cooling cooler, or the like may be used as the cooling unit. Furthermore, the metal base substrate 23 and the cooling unit may be integrally formed. In that case, the metal base substrate 23 and the cooling unit are made of aluminum, iron, silver, copper, or an alloy containing at least one of them which has high thermal conductivity. In addition, in order to improve corrosion resistance, a material, such as nickel, may be formed on the surface of the metal base substrate 23 integrally formed with the cooling unit by plating treatment or the like. To be concrete, a nickel-phosphorus alloy, a nickel-boron alloy, or the like may be used in place of nickel. The thickness of the metal base substrate 23 is preferably greater than or equal to 2 mm and smaller than or equal to 10 mm.

For example, the base circuit board 20 made up of the above parts is formed in the following way. First the metal base substrate 23, the insulating resin layer 22, and a conductive plate including the circuit patterns 21a and 21b are laminated in order and are pressure-bonded by heating and pressurization in the direction of laminating. They are pressure-bonded in an atmosphere of an active gas or in a vacuum. After that, masking is performed on the conductive plate with a photosensitive resist mask to determined patterns, patterns are formed by etching, and the photosensitive resist mask is removed. By doing so, the circuit patterns 21a and 21b are formed. A wafer on which the circuit patterns 21a and 21b are formed in this way is diced and the base circuit board 20 is obtained.

The semiconductor chips 31 and 32 are power devices made of silicon, silicon carbide, or gallium nitride. The semiconductor chip 31 includes a switching element. The switching element is a power MOSFET, an IGBT, or the like. For example, the semiconductor chip 31 has a drain electrode (positive electrode and a collector electrode in the case of an IGBT) as a main electrode on the back surface and has a gate electrode (control electrode) and a source electrode (negative electrode and an emitter electrode in the case of an IGBT) as main electrodes on the front surface. Furthermore, the semiconductor chip 32 includes a diode element. The diode element is a free wheeling diode (FWD) such as a Schottky barrier diode (SBD) or a P-intrinsic-N (PiN) diode. The semiconductor chip 32 has a cathode electrode as a main electrode on the back surface and has an anode electrode as a main electrode on the front surface. The back surfaces of the semiconductor chips 31 and 32 are bonded to the determined circuit pattern 21a with solder (not illustrated). The solder is Pb-free solder containing a determined alloy as a main ingredient. For example, the determined alloy is at least one of a tin-silver-copper alloy, a tin-zinc-bismuth alloy, a tin-copper alloy, and a tin-silver-indium-bismuth alloy. The solder may contain an additive such as nickel, germanium, cobalt, or silicon. The back surfaces of the semiconductor chips 31 and 32 may be bonded to the determined circuit pattern 21a by sintering by the use of a sintered material, such as silver, iron, copper, aluminum, titanium, nickel, tungsten, or molybdenum powder, in place of the solder. For example, the thickness of the semiconductor chips 31 and 32 is greater than or equal to 80 μm and smaller than or equal to 500 μm. The average of the thickness of the semiconductor chips 31 and 32 is about 200 μm. Electronic parts, such as a condenser, a resistor, a thermistor, a current sensor, and a control integrated circuit (IC), may be disposed at need over the circuit pattern 21a. Moreover, a semiconductor chip including an RC-IGBT in which an IGBT and an FWD are formed in one chip and which is a switching element may be disposed in place of the semiconductor chip 31 or 32. A case where a combination of semiconductor chips 31 and 32 is disposed over the base circuit board 20 illustrated in FIG. 1 is taken as an example. However, two or more combinations of semiconductor chips 31 and 32 may be disposed properly over the base circuit board 20 by design.

The bonding wires 33 electrically connect the semiconductor chips 31 and 32 and the circuit patterns 21a and 21b, the semiconductor chip 31 and the semiconductor chip 32, and the circuit patterns 21a and 21b and lead terminals 47 properly. The bonding wires 33 are made of a material, such as gold, silver, copper, aluminum, or an alloy containing at least one of them, having good electrical conductivity. In addition, for example, the diameter of the bonding wires 33 is greater than or equal to 110 μm and smaller than or equal to 500 μm. FIG. 1 illustrates a case where the circuit pattern 21a and the lead terminal 47 described later, the semiconductor chip 31 and the semiconductor chip 32, the semiconductor chip 32 and the circuit pattern 21b, and the circuit pattern 21b and the lead terminal 47 are electrically connected by the bonding wires 33. As a result, the semiconductor chips 31 and 32 are electrically connected via the circuit patterns 21a and 21b and the bonding wires 33 to the lead terminals 47. Furthermore, the circuit patterns 21a and 21b may be electrically connected to the lead terminals 47 by the use of a lead frame in place of the bonding wires 33. Alternatively, one end portion of each lead terminal 47 in the case 40 may be extended to directly connect the lead terminals 47 to the circuit patterns 21a and 21b.

The case 40 includes a frame body portion 41 and the lead terminals 47 located in the frame body portion 41. The frame body portion 41 and the lead terminals 47 are integrally formed by injection molding by the use of a thermoplastic resin which is able to be bonded to the lead terminals 47. Polyphenylene sulfide (PPS), polybutylene terephthalate (PBT) resin, polybutylene succinate (PBS) resin, polyamide resin, acrylonitrile butadiene styrene (ABS) resin, or the like is used as such a thermoplastic resin. The frame body portion 41 includes an upper opening 42a having a central portion piercing from the front surface to the back surface and a lower opening 46a under the upper opening 42a and has the shape of a frame in planar view. The upper opening 42a communicates with the lower opening 46a.

The frame body portion 41 includes an upper inner wall portion 42, a middle inner wall portion 44, and a lower inner wall portion 46 in order from the top (sealing member 52). The upper inner wall portion 42 faces the upper opening 42a and demarcates the upper opening 42a. The middle inner wall portion 44 and the lower inner wall portion 46 face the lower opening 46a and demarcates the lower opening 46a. In this case, the middle inner wall portion 44 protrudes from the upper inner wall portion 42 to the side of the lower opening 46a and an upper level difference portion 43 is formed between the middle inner wall portion 44 and the upper inner wall portion 42. The upper level difference portion 43 is formed at least in a position in which the lead terminal 47 is located. With the semiconductor device 10 the lead terminals 47 are formed on the short sides of the case 40 opposite each other with the upper opening 42a therebetween. As a result, there is need to form the upper level difference portions 43 at least on the short sides of the case 40 opposite each other with the upper opening 42a therebetween. FIG. 2 illustrates a case where the upper level difference portions 43 are formed along the outer edge of the upper opening 42a.

Furthermore, a support portion 41a of the frame body portion 41 including the lower inner wall portion 46 protrudes from the middle inner wall portion 44 to the side of the lower opening 46a and a lower level difference portion 45 is formed between the lower inner wall portion 46 and the middle inner wall portion 44. The base circuit board 20 is housed in the lower opening 46a in a state in which it is supported on the support portion 41a of the frame body portion 41. At this time the middle inner wall portion 44 and the lower inner wall portion 46 surround an outer peripheral side surface 20a of the base circuit board 20. Furthermore, the lower inner wall portion 46 is in surface contact with the outer peripheral side surface 20a of the base circuit board 20 (metal base substrate 23). The lower inner wall portion 46 adheres to the outer peripheral side surface 20a of the metal base substrate 23 with an adhesive member 51 and is in surface contact with it. The distance between the lower inner wall portion 46 and the outer peripheral side surface 20a of the base circuit board 20 (metal base substrate 23) is greater than or equal to 0.10 mm and smaller than or equal to 1.20 mm. The adhesive member 51 is applied to the outer peripheral side surface 20a between the lower inner wall portion 46 and the outer peripheral side surface 20a of the base circuit board 20. For example, a thermosetting resin-based adhesive member or an organic adhesive member is used as the adhesive member 51. A thermosetting resin-based adhesive member contains epoxy resin, phenolic resin, or the like as a main ingredient. An organic adhesive member is an elastomer-based adhesive containing silicone rubber, chloroprene rubber, or the like as a main ingredient. The back surface of the base circuit board 20 housed in this way and the back surface of the case 40 belong to the same plane. In addition, at this time the middle inner wall portion 44 is apart from the outer peripheral side surface 20a of the base circuit board 20 and there is a gap 53. That is to say, the gap 53 is formed so as to surround the base circuit board 20 along the outer peripheral side surface 20a of the base circuit board 20. Moreover, the width of the gap 53 is preferably greater than or equal to 1.00 mm and smaller than or equal to 10.00 mm. As described later, if the width of the gap 53 is smaller than 1.0 mm, then the sealing member 52 which enters the gap 53 is apt to break. If the width of the gap 53 is greater than 10.00 mm, then it is difficult to miniaturize the semiconductor device 10. Accordingly, the width of the gap 53 is more preferably greater than or equal to 2.00 mm and smaller than or equal to 5.00 mm. The gap 53 formed by the middle inner wall portion 44, the outer peripheral side surface 20a of the base circuit board 20, and the lower level difference portion 45 is sealed with the sealing member 52 described later.

For example, the lead terminals 47 illustrated in FIG. 1 have the shape of the letter “L” in side view. One end portion of each lead terminal 47 protrudes from the top of the frame body portion 41 of the case 40 and the other end portion of each lead terminal 47 is exposed from the upper level difference portions 43 of the frame body portion 41. The lead terminals 47 are made of a material, such as copper, aluminum, or an alloy containing at least one of them, having good electrical conductivity. The thickness of the lead terminals 47 is preferably greater than or equal to 1.00 mm and smaller than or equal to 2.00 mm. The thickness of the lead terminals 47 is more preferably greater than or equal to 1.20 mm and smaller than or equal to 1.50 mm. The bonding wire 33 is connected electrically and mechanically to the other end portion of each lead terminal 47 exposed from the upper level difference portion 43. Plating treatment may also be performed on the lead terminals 47 by the use of a material, such as aluminum, nickel, titanium, chromium, molybdenum, tantalum, niobium, tungsten, vanadium, bismuth, zirconium, hafnium, gold, silver, platinum, palladium, or an alloy containing at least one of them, having high corrosion resistance.

The upper opening 42a in the case 40 and the front surface of the base circuit board 20 are sealed with the sealing member 52. The sealing member 52 contains a thermosetting resin and a filler contained in the thermosetting resin. For example, a thermosetting resin is epoxy resin, phenolic resin, maleimide resin, or polyester resin. An example of the sealing member 52 is epoxy resin.

The epoxy resin contains silicon oxide, aluminum oxide, boron nitride, aluminum nitride, or the like as a filler. Furthermore, a thermoplastic resin, such as PPS resin, PBT resin, PBS resin, PA resin, or ABS resin, may be used as the sealing member 52.

In order to seal the inside of the case 40 with the sealing member 52, the sealing member 52 in a molten state is injected into the case 40. At this time there is need to keep the viscosity of the sealing member 52 in a molten state. Accordingly, the sealing member 52, the case 40, and the semiconductor chips 31 and 32 are heated so as to keep a determined temperature. Furthermore, the sealing member 52 is injected in a vacuum. By doing so, a void is not generated and the sealing member 52 spreads in all the corners of the case 40. In addition, before the sealing member 52 is injected, deaeration is performed in a vacuum in order to remove a void. After the deaeration is performed, the sealing member 52 in a molten state is agitated in a vacuum to perform complete deaeration. This further suppresses the generation of a void. Alternatively, when the sealing member 52 in a molten state is injected, ultrasonic vibration is given to the case 40, the base circuit board 20, and the like. This suppresses the generation of a void in the sealing member 52 more reliably.

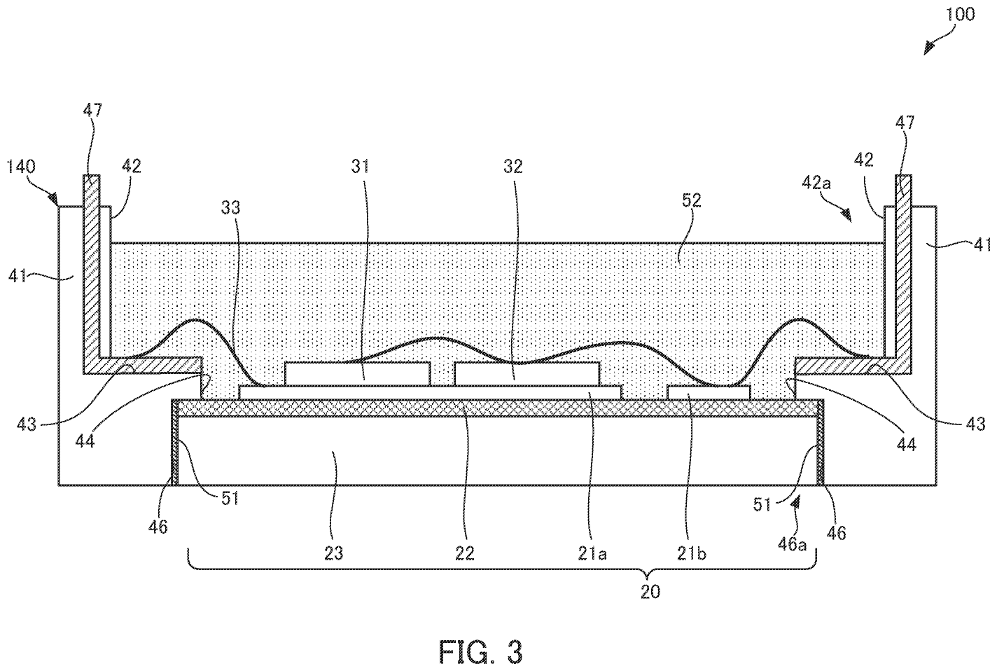

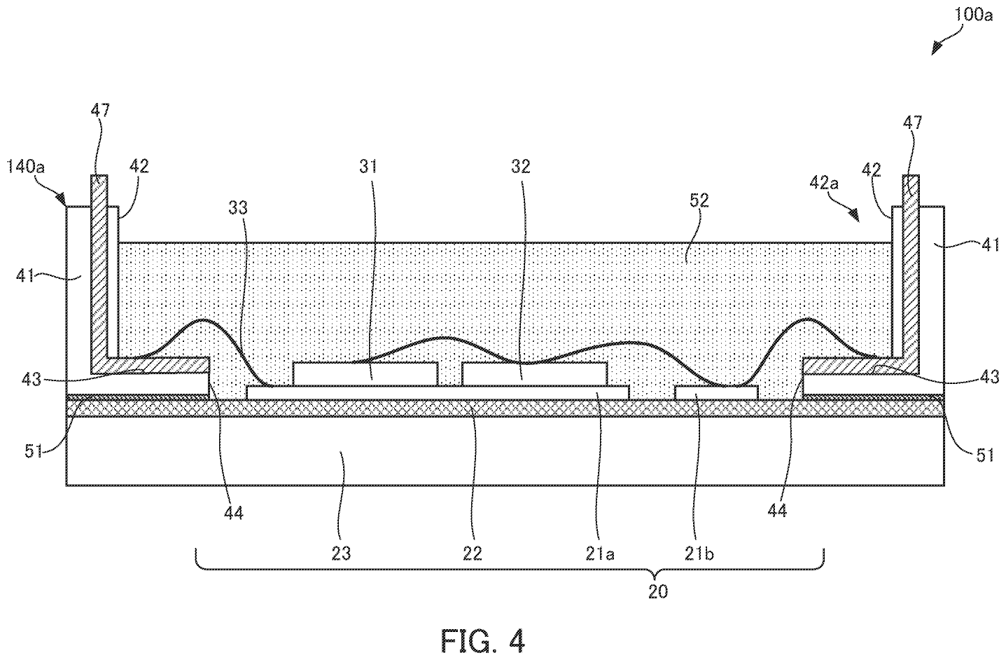

A reference example for the above semiconductor device 10 will now be described by the use of FIG. 3 and FIG. 4. Each of FIG. 3 and FIG. 4 is a longitudinal sectional view of a semiconductor device taken as a reference example. Parts of semiconductor devices 100 and 100a illustrated in FIG. 3 and FIG. 4, respectively which are the same as those of the semiconductor device 10 are marked with the same numerals and descriptions of them will be omitted or simplified.

With the semiconductor device 100, as illustrated in FIG. 3, a middle inner wall portion 44 of a case 140 protrudes from a lower inner wall portion 46 to the side of a lower opening 46a. Furthermore, a base circuit board 20 is housed in the lower opening 46a and is adhered to the lower inner wall portion 46 with an adhesive member 51 therebetween. When semiconductor chips 31 and 32 are energized, the semiconductor device 100 generates heat and its temperature rises. As a result, a sealing member 52 is apt to peel off due to curing shrinkage of the sealing member 52. In particular, the sealing member 52 is apt to peel off between the middle inner wall portion 44 of the case 140 and a circuit pattern 21a or between the middle inner wall portion 44 of the case 140 and a circuit pattern 21b. Furthermore, stress created between the base circuit board 20 and the sealing member 52 or between the case 140 and the sealing member 52 according to the difference in thermal expansion coefficient between the base circuit board 20, the case 140, and the sealing member 52 also contributes to peeling. The insulating property of the semiconductor device 100 may deteriorate or an electric discharge may occur, with peeling which occurs in this way as the starting point. In addition, the base circuit board 20 may break away from the lower opening 46a of the case 140 because of the difference in thermal expansion coefficient between the base circuit board 20 and the case 140.

Furthermore, with a case 140a of the semiconductor device 100a, as illustrated in FIG. 4, the portion including the lower inner wall portion 46 is removed from the case 140 of FIG. 3. A base circuit board 20 is adhered to the back surface of the case 140a with an adhesive member 51. When the temperature of the semiconductor device 100a rises, a sealing member 52 is apt to peel off due to curing shrinkage of the sealing member 52. This is the same with the semiconductor device 100. In particular, the sealing member 52 is apt to peel off between a middle inner wall portion 44 of the case 140a and a circuit pattern 21a or between a middle inner wall portion 44 of the case 140a and a circuit pattern 21b. The insulating property of the semiconductor device 100a may deteriorate or an electric discharge may occur, with peeling which occurs in this way as the starting point. Moreover, with the semiconductor device 100a the base circuit board 20 may break away from the case 140a because of the difference in thermal expansion coefficient between the base circuit board 20 and the case 140a, in addition to such peeling.

On the other hand, the semiconductor device 10 illustrated in FIG. 1 and FIG. 2 includes the base circuit board 20, the case 40, and the sealing member 52. The base circuit board 20 includes the metal base substrate 23, the insulating resin layer 22 formed over the front surface of the metal base substrate 23, and the circuit patterns 21a and 21b formed over the front surface of the insulating resin layer 22. The case 40 demarcates the lower opening 46a in which the base circuit board 20 is housed and includes an inner wall surface (middle inner wall portion 44 and the lower inner wall portion 46) which surrounds the outer peripheral side surface 20a of the base circuit board 20 housed in the lower opening 46a. The base circuit board 20 in the lower opening 46a is sealed with the sealing member 52 from the side of the circuit patterns 21a and 21b. At this time the lower inner wall portion 46 of the inner wall surface is in surface contact with the outer peripheral side surface 20a of the base circuit board 20. The middle inner wall portion 44 is situated on the side of the sealing member 52 from the lower inner wall portion 46 and is apart from the outer peripheral side surface 20a of the base circuit board 20. As a result, the gap 53 is formed. Furthermore, the gap 53 is sealed with the sealing member 52. Accordingly, the sealing member 52 surrounds the outer periphery (gap 53) of the base circuit board 20. This suppresses deviation of the base circuit board 20 in the horizontal direction in FIG. 1 (and in the direction perpendicular to the page of FIG. 1). In addition, the sealing member 52 in the gap 53 engages with the support portion 41a of the case 40 in the upward or downward direction in FIG. 1. This prevents the base circuit board 20 from breaking away from the lower opening 46a. As stated above, a positional deviation of the base circuit board 20 relative to the case 40 is suppressed and peeling of the sealing member 52 is prevented. Accordingly, deterioration in the reliability of the semiconductor device 10 is suppressed.

### Second Embodiment

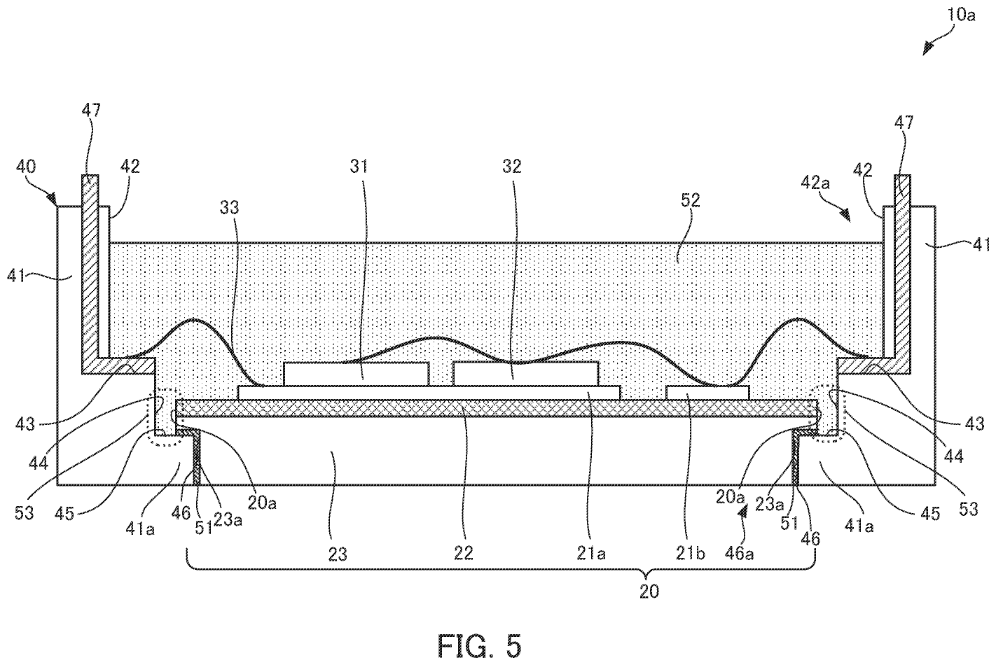

In a second embodiment, a case where a notch portion is formed in the metal base substrate 23 of the base circuit board 20 of the semiconductor device 10 according to the first embodiment will be described by the use of FIG. 5. FIG. 5 is a longitudinal sectional view of a semiconductor device according to a second embodiment. Parts of a semiconductor device 10a illustrated in FIG. 5 which are the same as those of the semiconductor device 10 are marked with the same numerals and descriptions of them will be omitted or simplified.

A notch portion 23a is formed in an outer edge portion of the bottom of a metal base substrate 23 of the semiconductor device 10a. As illustrated in FIG. 5, the notch portion 23a is rectangular. Because the notch portion 23a is formed simply by performing an easy cutting process on the metal base substrate 23, the manufacturing costs do not increase significantly. The width of the notch portion 23a is greater than or equal to 0.50 mm and smaller than or equal to 5.00 mm. The width of the notch portion 23a is preferably smaller than or equal to, at most, 1.20 mm. Furthermore, a support portion 41a of a case 40 protrudes to the side of a lower opening 46a and is in surface contact with the notch portion 23a. A lower inner wall portion 46 of the support portion 41a and part of the top of an end portion of the support portion 41a are adhered to the notch portion 23a with an adhesive member 51.

With the above semiconductor device 10a a sealing member 52 surrounds the outer periphery (gap 53) of a base circuit board 20. This suppresses deviation of the base circuit board 20 in the horizontal direction in FIG. 5 (and in the direction perpendicular to the page of FIG. 5). This is the same with the semiconductor device 10. In addition, the sealing member 52 in the gap 53 engages with the support portion 41a of the case 40 in the upward or downward direction in FIG. 5. Moreover, the support portion 41a of the case 40 engages with the notch portion 23a of the metal base substrate 23 of the base circuit board 20 in the upward or downward direction in FIG. 5. This prevents the base circuit board 20 from breaking away from the lower opening 46a, compared with the case of the first embodiment. As stated above, a positional deviation of the base circuit board 20 relative to the case 40 is suppressed and peeling of the sealing member 52 is prevented. Accordingly, deterioration in the reliability of the semiconductor device 10a is suppressed.

### Third Embodiment

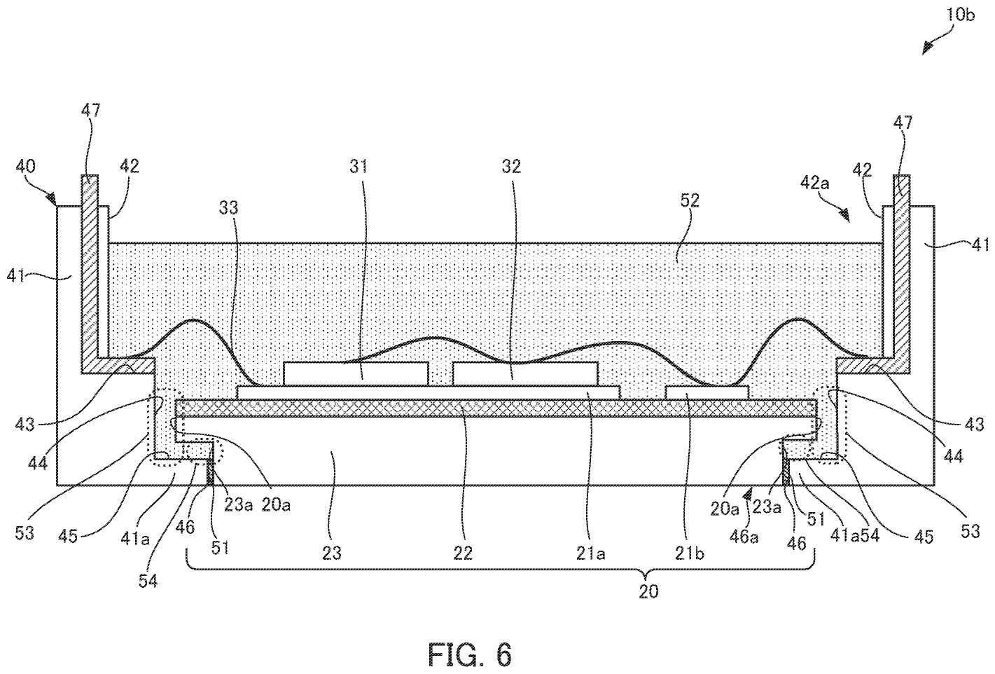

In a third embodiment, a notch portion is formed in a metal base substrate 23 of a base circuit board 20. This is the same with the semiconductor device 10a according to the second embodiment. In the third embodiment, however, another case will be described by the use of FIG. 6. FIG. 6 is a longitudinal sectional view of a semiconductor device according to the third embodiment. Parts of a semiconductor device 10b illustrated in FIG. 6 which are the same as those of the semiconductor device 10 are marked with the same numerals and descriptions of them will be omitted or simplified.

A notch portion 23a is formed in an outer edge portion of the bottom of the metal base substrate 23 of the semiconductor device 10b. This is the same with the semiconductor device 10a according to the second embodiment. As illustrated in FIG. 6, the notch portion 23a is rectangular. The width of the notch portion 23a is greater than or equal to 0.50 mm and smaller than or equal to 5.00 mm. The width of the notch portion 23a is preferably smaller than or equal to, at most, 1.20 mm. Furthermore, a support portion 41a of a case 40 protrudes to the side of a lower opening 46a and is in surface contact with the notch portion 23a. With the semiconductor device 10b, however, a lower inner wall portion 46 of the support portion 41a is in surface contact with the notch portion 23a with an adhesive member 51 therebetween and a gap 54 is formed between the top of the support portion 41a and a surface of the notch portion 23a on the side of an upper opening 42a. The gap 54 communicates with a gap 53. Accordingly, with the semiconductor device 10b the gaps 53 and 54 are sealed with a sealing member 52.

With the above semiconductor device 10b the sealing member 52 surrounds the outer periphery (gaps 53 and 54) of the base circuit board 20 so as to hold it. This reliably suppresses deviation of the base circuit board 20 in the horizontal direction in FIG. 6 (and in the direction perpendicular to the page of FIG. 6), compared with the case of the second embodiment. In addition, the sealing member 52 in the gaps 53 and 54 engages with the support portion 41a of the case 40 in the upward or downward direction in FIG. 6. This prevents the base circuit board 20 from breaking away from the lower opening 46a, compared with the case of the first embodiment. As stated above, a positional deviation of the base circuit board 20 relative to the case 40 is suppressed and peeling of the sealing member 52 is prevented. Accordingly, deterioration in the reliability of the semiconductor device 10b is suppressed.

### Fourth Embodiment

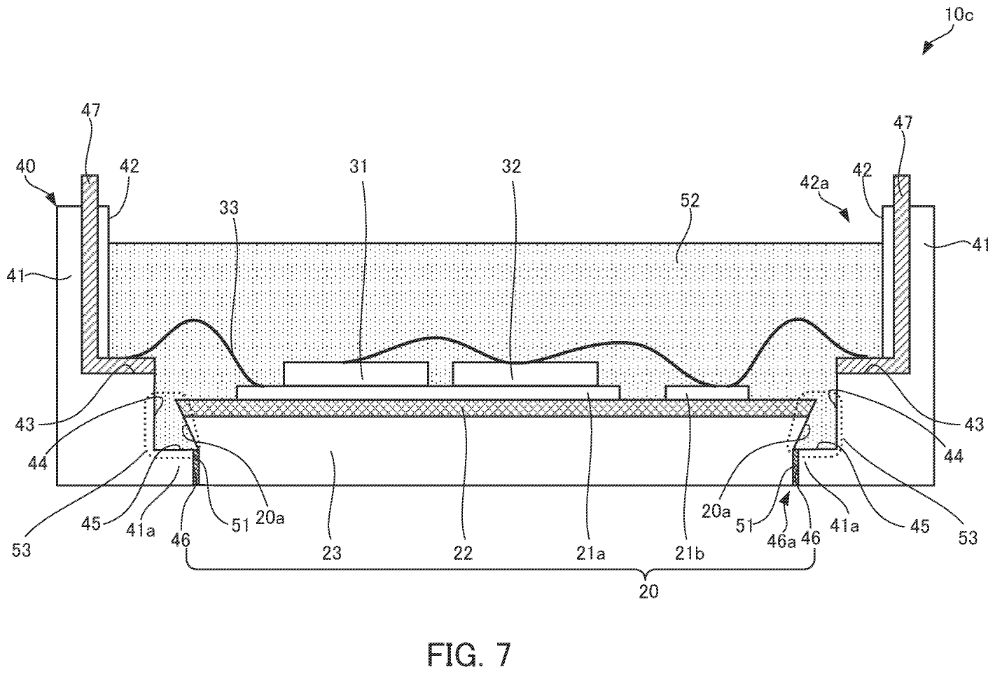

In a fourth embodiment, a case where an upper portion of the outer peripheral side surface 20a on the front surface side of the base circuit board 20 of the semiconductor device 10 according to the first embodiment is worked so as to have a taper shape will be described by the use of FIG. 7. FIG. 7 is a longitudinal sectional view of a semiconductor device according to a fourth embodiment. Parts of a semiconductor device 10c illustrated in FIG. 7 which are the same as those of the semiconductor device 10 are marked with the same numerals and descriptions of them will be omitted or simplified.

An upper portion of an outer peripheral side surface 20a of a base circuit board 20 of the semiconductor device 10c is worked so as to have a taper shape. To be concrete, as illustrated in FIG. 7, the outer peripheral side surface 20a of the base circuit board 20 narrows from the front surface to the back surface and becomes perpendicular to the back surface halfway. Furthermore, a support portion 41a of a case 40 protrudes to the side of a lower opening 46a and is in surface contact with a perpendicular portion of the outer peripheral side surface 20a with an adhesive member 51 therebetween. In this case, the volume of a gap 53 is greater than that of the gap 53 in the first embodiment and the gap 53 is formed so as to surround the base circuit board 20.

With the above semiconductor device 10c a sealing member 52 surrounds the outer periphery (gap 53) of the base circuit board 20 so as to hold it. This is the same with the semiconductor device 10. This reliably suppresses deviation of the base circuit board 20 in the horizontal direction in FIG. 7 (and in the direction perpendicular to the page of FIG. 7), compared with the first or second embodiment. In addition, the sealing member 52 in the gap 53 engages with the support portion 41a of the case 40 in the upward or downward direction in FIG. 7. This prevents the base circuit board 20 from breaking away from the lower opening 46a, compared with the case of the first or second embodiment. As stated above, a positional deviation of the base circuit board 20 relative to the case 40 is suppressed and peeling of the sealing member 52 is prevented. Accordingly, deterioration in the reliability of the semiconductor device 10c is suppressed.

### Fifth Embodiment

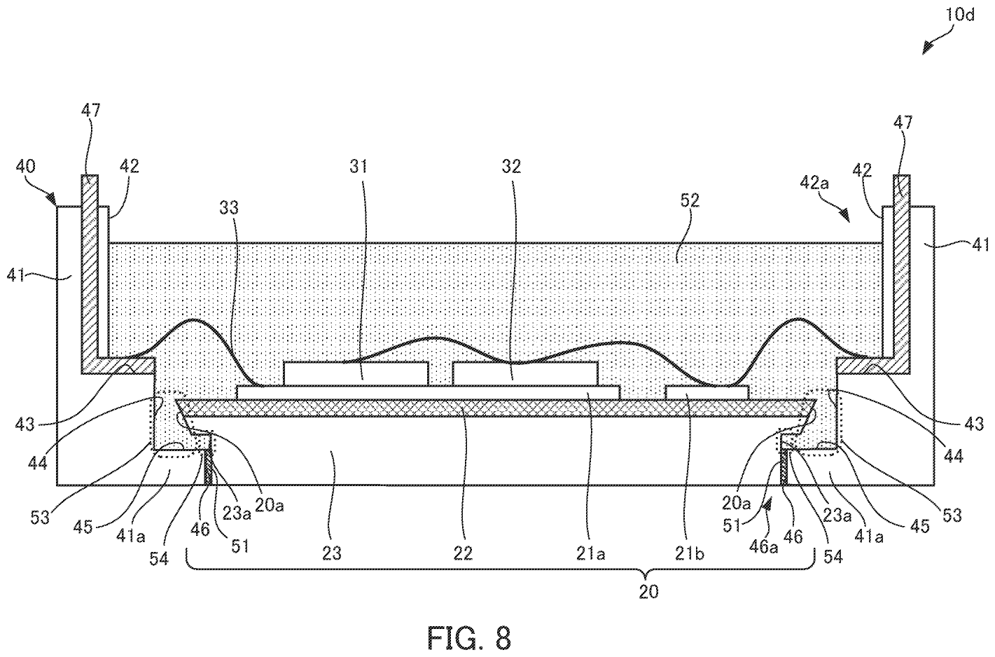

In the fourth embodiment the upper portion of the outer peripheral side surface 20a of the base circuit board 20 of the semiconductor device 10c is worked so as to have a taper shape. In a fifth embodiment, a case where a notch portion is formed further in the base circuit board 20 of the semiconductor device 10c according to the fourth embodiment will be described by the use of FIG. 8. FIG. 8 is a longitudinal sectional view of a semiconductor device according to a fifth embodiment. Parts of a semiconductor device 10d illustrated in FIG. 8 which are the same as those of the semiconductor device 10 are marked with the same numerals and descriptions of them will be omitted or simplified.

An upper portion of an outer peripheral side surface 20a of a base circuit board 20 of the semiconductor device 10d is worked so as to have a taper shape. Furthermore, a notch portion 23a is formed in a lower portion of the outer peripheral side surface 20a. To be concrete, as illustrated in FIG. 8, the outer peripheral side surface 20a of the base circuit board 20 narrows from the front surface to the back surface and becomes perpendicular to the back surface halfway. In addition, the notch portion 23a is formed in a perpendicular portion of the outer peripheral side surface 20a. Moreover, a support portion 41a of a case 40 protrudes to the side of a lower opening 46a and is in surface contact with the notch portion 23a with an adhesive member 51 therebetween. A gap 54 is formed between the top of the support portion 41a and the top of the notch portion 23a. The gap 54 communicates with a gap 53. Accordingly, with the semiconductor device 10d the gaps 53 and 54 are sealed with a sealing member 52. In this case, the total volume of the gaps 53 and 54 is greater than the volume of the gap 53 in the fourth embodiment and the gaps 53 and 54 are formed so as to surround the base circuit board 20.

With the above semiconductor device 10d the sealing member 52 surrounds the outer periphery (gaps 53 and 54) of the base circuit board 20 so as to hold it. This reliably suppresses deviation of the base circuit board 20 in the horizontal direction in FIG. 8 (and in the direction perpendicular to the page of FIG. 8), compared with the case of the fourth embodiment. In addition, the sealing member 52 in the gaps 53 and 54 engages with the support portion 41a of the case 40 in the upward or downward direction in FIG. 8. This prevents the base circuit board 20 from breaking away from the lower opening 46a, compared with the case of the first embodiment. As stated above, a positional deviation of the base circuit board 20 relative to the case 40 is suppressed and peeling of the sealing member 52 is prevented. Accordingly, deterioration in the reliability of the semiconductor device 10d is suppressed.

### Sixth Embodiment

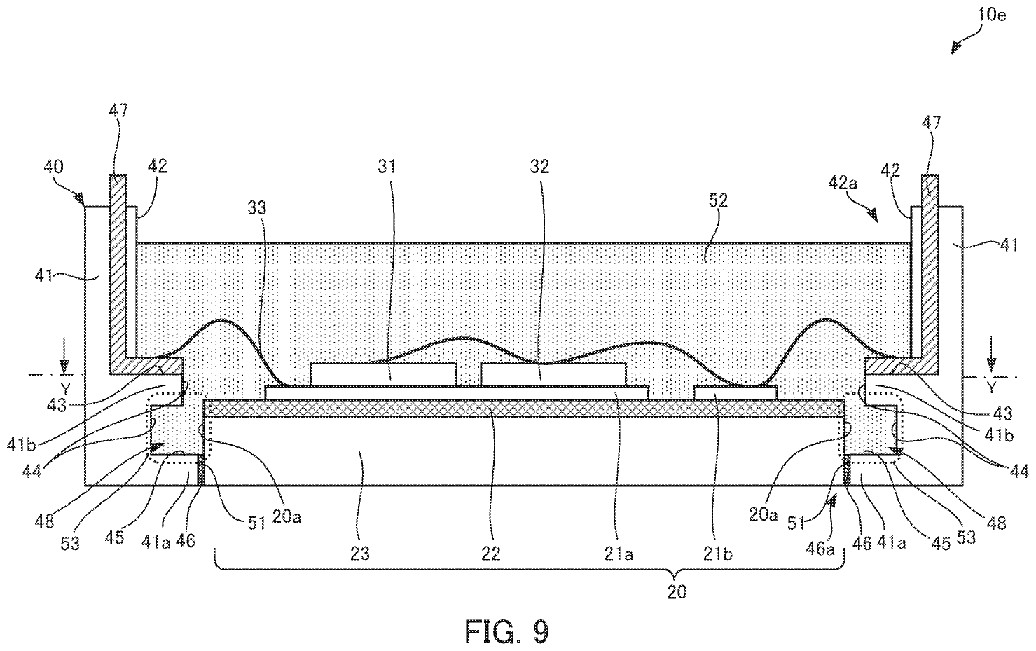

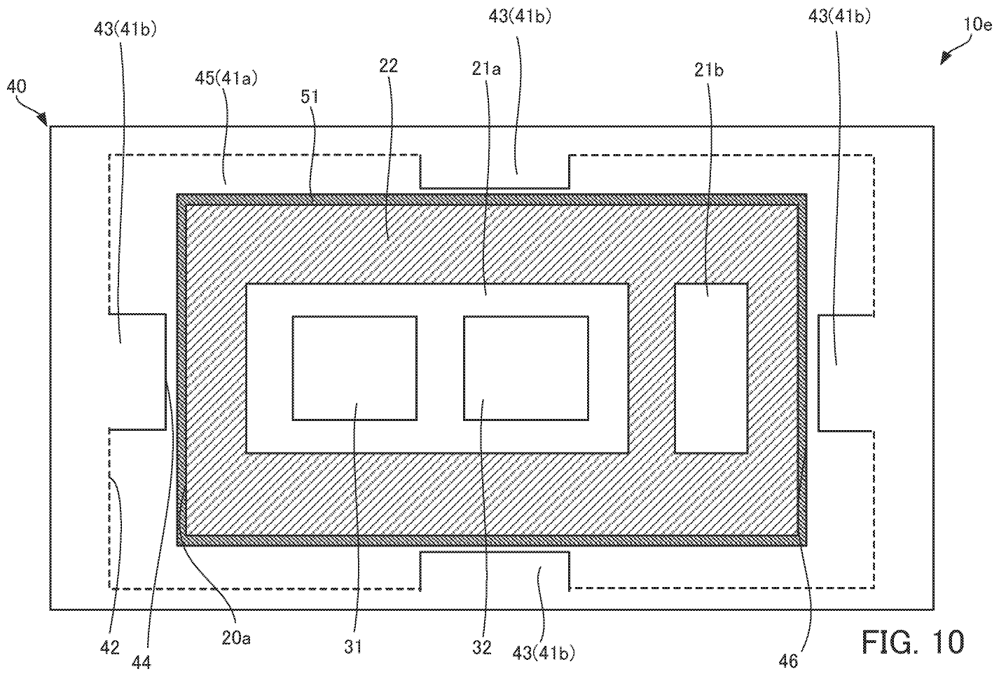

In a sixth embodiment a case where a concave portion is formed in the middle inner wall portion 44 of the case 40 of the semiconductor device 10 according to the first embodiment to widen the gap 53 will be described by the use of FIG. 9 and FIG. 10. FIG. 9 is a longitudinal sectional view of a semiconductor device according to a sixth embodiment. FIG. 10 is a transverse sectional view of the semiconductor device according to the sixth embodiment. FIG. 10 is a sectional view taken along the dot-dash line Y-Y of FIG. 9. A sealing member 52 and bonding wires 33 are not illustrated in FIG. 10. Furthermore, parts of a semiconductor device 10e illustrated in FIG. 9 and FIG. 10 which are the same as those of the semiconductor device 10 are marked with the same numerals and descriptions of them will be omitted or simplified.

As illustrated in FIG. 9, a concave portion 48 is formed in a middle inner wall portion 44 of a case 40 of the semiconductor device 10e on the opposite side of a base circuit board 20. Furthermore, the concave portion 48 is formed under an upper level difference portion 43. As a result, a frame body portion 41 has a support portion 41a in a lower part and a protrusion 41b over the support portion 41a. As illustrated in FIG. 10, the upper level difference portions 43 are formed at least in positions opposite each other on the short sides of the frame body portion 41 of the case 40 of the semiconductor device 10e according to the sixth embodiment in which lead terminals 47 are located. In addition, in the sixth embodiment, upper level difference portions 43 are formed in positions opposite each other on the long sides of the frame body portion 41 and concave portions 48 (not illustrated) are formed under the upper level difference portions 43. In the first embodiment the upper level difference portions 43 are formed along the outer edge of the upper opening 42a. In that case, concave portions 48 may be formed under the upper level difference portions 43 along the outer edge of the upper opening 42a. The concave portions 48 illustrated in FIG. 9 are rectangular. However, the concave portions 48 may have a semicircular, semielliptical, or triangular shape in cross-sectional view. Moreover, the generation of a void in the sealing member 52 with which the concave portion 48 is sealed is suppressed by giving curvature to corners of the concave portion 48. As stated above, a gap 53 between the middle inner wall portion 44 of the case 40 and an outer peripheral side surface 20a of the base circuit board 20 is wider than the gap 53 in the first embodiment. The width of the concave portion 48 in the gap 53 illustrated in FIG. 9 depends on the thickness of the frame body portion 41 of the case 40. However, for example, it is desirable that the width of the concave portion 48 in the gap 53 be greater than or equal to 1.00 mm and smaller than or equal to 2.00 mm.

With the above semiconductor device 10e the sealing member 52 surrounds the outer periphery (gap 53) of the base circuit board 20. This is the same with the semiconductor device 10. With the semiconductor device 10e, however, the volume of the gap 53 is great compared with the case of the semiconductor device 10. This reliably suppresses deviation of the base circuit board 20 in the horizontal direction in FIG. 9 (and in the direction perpendicular to the page of FIG. 9), compared with the case of the semiconductor device 10. In addition, the sealing member 52 in the gap 53 engages with the support portion 41a of the case 40 in the upward or downward direction in FIG. 9. Moreover, with the semiconductor device 10e the whole of the protrusion 41b of the frame body portion 41 is sealed with the sealing member 52. Accordingly, the protrusion 41b achieves an anchor effect and a positional deviation of the case 40 relative to the sealing member 52 is suppressed. This reliably prevents the base circuit board 20 from breaking away from a lower opening 46a, compared with the case of the first embodiment. As stated above, a positional deviation of the base circuit board 20 relative to the case 40 is suppressed and peeling of the sealing member 52 is prevented. Accordingly, deterioration in the reliability of the semiconductor device 10e is suppressed.

### Seventh Embodiment

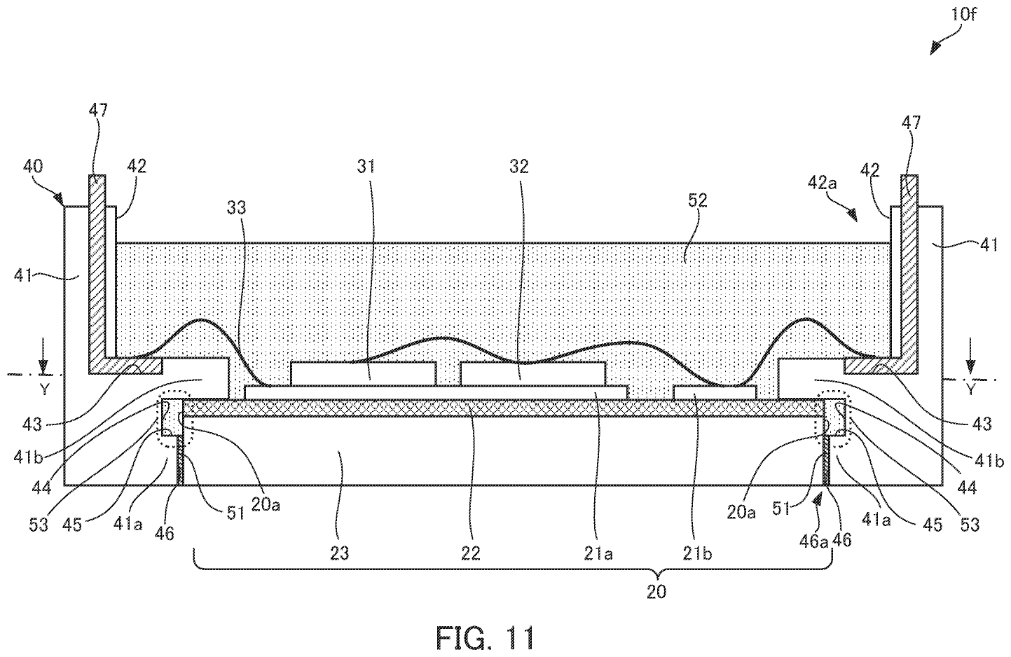

In a seventh embodiment a case where an upper portion of the middle inner wall portion 44 of the frame body portion 41 of the semiconductor device 10 according to the first embodiment protrudes to the side of the base circuit board 20 will be described by the use of FIG. 11. FIG. 11 is a longitudinal sectional view of a semiconductor device according to a seventh embodiment. Furthermore, parts of a semiconductor device 10f illustrated in FIG. 11 which are the same as those of the semiconductor device 10 are marked with the same numerals and descriptions of them will be omitted or simplified.

With the semiconductor device 10f a protrusion 41b protrudes from an upper portion of a middle inner wall portion 44 of a frame body portion 41 to the side of a base circuit board 20, compared with the semiconductor device 10. The back surface of an end portion of the protrusion 41b is in contact with an insulating resin layer 22 of the base circuit board 20. With the semiconductor device 10f the protrusion 41b of the frame body portion 41 is formed on each of the short sides and long sides of the frame body portion 41 (see FIG. 10). As illustrated in FIG. 11, a sealing member 52 injected into a case 40 reliably spreads between the case 40 and the base circuit board 20 by forming the protrusions 41b in this way.

With the above semiconductor device 10f the sealing member 52 surrounds the outer periphery (gap 53) of the base circuit board 20. This is the same with the semiconductor device 10. This suppresses deviation of the base circuit board 20 in the horizontal direction in FIG. 11 (and in the direction perpendicular to the page of FIG. 11). In addition, the sealing member 52 in the gap 53 engages with the support portion 41a of the case 40 in the upward or downward direction in FIG. 11. This prevents the base circuit board 20 from breaking away from a lower opening 46a, compared with the case of the first embodiment. Moreover, with the semiconductor device 10f the protrusion 41b of the case 40 is in contact with the insulating resin layer 22 of the base circuit board 20. This suppresses a warp of the base circuit board 20 caused by a difference in thermal expansion coefficient. Furthermore, stress concentration in the semiconductor device 10f is relaxed and a contribution is made toward suppressing peeling of the sealing member 52. As stated above, a positional deviation of the base circuit board 20 relative to the case 40 is suppressed and peeling of the sealing member 52 is prevented. Accordingly, deterioration in the reliability of the semiconductor device 10f is suppressed.

With the semiconductor device having the above structure, peeling of a sealing member is suppressed and deterioration in the reliability is suppressed.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that various changes, substitutions, and alterations could be made hereto without departing from the spirit and scope of the invention.

What is claimed is:

1. A semiconductor device comprising:
a base circuit board including
a metal base substrate,
a resin layer formed on a front surface of the metal base substrate, and
a circuit pattern formed on a front surface of the resin layer;
a case which surrounds the base circuit board to demarcate, in a plan view of the semiconductor device, an opening area in which the base circuit board is disposed; and
a sealing member that seals the base circuit board disposed in the case, wherein
the case has an inner wall surface that faces an outer peripheral side surface of the base circuit board, and that includes:
a first inner wall portion which is in surface contact with an outer peripheral side surface of the metal base substrate; and
a second inner wall portion that is separate from the outer peripheral side surface of the base circuit board, to thereby have a first gap therebetween that is filled with the sealing member.

2. The semiconductor device according to claim 1, wherein the first inner wall portion is in surface contact with the outer peripheral side surface of the metal base substrate with an adhesive member therebetween.

3. The semiconductor device according to claim 2, wherein the case includes a support portion protruding toward the outer peripheral side surface of the metal base substrate, a surface of the support portion facing the outer peripheral side surface of the metal base substrate being the first inner wall portion, and a portion of the inner wall surface of the case adjacent to the support portion being the second inner wall portion.

4. The semiconductor device according to claim 3, wherein:
the outer peripheral side surface of the metal base substrate has a notch portion; and
the support portion protrudes into the notch portion, and the first inner wall portion is in surface contact with the notch portion.

5. The semiconductor device according to claim 4, wherein the support portion protrudes into the notch portion to form a second gap therebetween, the second gap communicating with the first gap and being filled with the sealing member.

6. The semiconductor device according to claim 4, wherein a portion of the metal base substrate at the front surface thereof and the resin layer formed thereon have a tapered edge, such that the first gap gradually narrows along a direction that is from the metal base substrate to the resin layer and is perpendicular to the front surface of the metal base substrate.

7. The semiconductor device according to claim 1, wherein
the second inner wall portion of the case has a concave portion facing the outer peripheral side surface of the base circuit board, the concave portion being filled with the sealing member.

8. The semiconductor device according to claim 1, wherein the case has a protrusion protruding inward in the plan view of the semiconductor device from the second inner wall portion.

9. The semiconductor device according to claim 8, wherein a back surface of an end portion of the protrusion is in contact with the resin layer of the base circuit board.

10. The semiconductor device according to claim 1, wherein the second inner wall portion and an outer peripheral side surface of the resin layer are separated from each other by the sealing member in the first gap.
